(19) United States
(12) Patent Application Publication
(10) Pub. No.: US 2024/0243371 A1
(43) Pub. Date: Jul. 18, 2024

(54) Enhanced Single-Cell Energy Management System

(71) Applicant: RJ1 Holdings Inc., San Antonio, TX (US)

(72) Inventor: David Daekyum Kim, Colorado Springs, CO (US)

(21) Appl. No.: 18/408,982

(22) Filed: Jan. 10, 2024

Related U.S. Application Data
(60) Provisional application No. 63/479,818, filed on Jan. 13, 2023.
(60) Provisional application No. 63/581,999, filed on Sep. 12, 2023.
(60) Provisional application No. 63/595,387, filed on Nov. 2, 2023.
(60) Provisional application No. 63/605,234, filed on Dec. 1, 2023.

(51) Int. Cl. H01M 10/42; G01R 31/382; G01R 31/392; G01R 31/396; H01M 10/48; H01M 50/202; H01M 50/581; H02J 7/00

(52) U.S. Cl. CPC H01M 10/425; G01R 31/382; G01R 31/392; G01R 31/396; H01M 10/482; H01M 10/486; H01M 50/202; H01M 50/581; H02J 7/0031; H01M 2010/4271; H01M 2010/4278; H01M 2200/10

(57) ABSTRACT

A battery system is provided having first and second battery cells in a battery pack. A first battery management system (BMS) may be in communication with the first battery cell, while a second battery management system may be in communication with the second battery cell. In this manner, each BMS may function to locally control each respective battery cell, thereby providing improved control over each cell. The BMSs may include controllers configured to receive measurement data from the battery cells, to process this battery cell measurement data, and then to produce a control signal based on the battery cell measurement data. The control signals may be provided to switching circuitry connected to the battery cell, thereby allowing for individualized control of each battery cell. Additionally, each BMS may share information regarding the individual cell they monitor with other BMSs. Because each battery cell may be associated with its own BMS, manufacturability, flexibility, and safety improvements may be achieved, among other advantages.

### CROSS-REFERENCE TO RELATED APPLICATIONS

This application claims the benefit of U.S. Provisional Applications Nos. 63/479,818 filed Jan. 13, 2023, 63/581,999 filed Sep. 12, 2023, 63/595,387 filed Nov. 2, 2023, and 63/605,234 filed Dec. 1, 2023. The entirety of each of the priority applications is incorporated herein by reference.

### TECHNICAL FIELD

The subject matter described herein generally relates to systems and methods to be incorporated into energy storage systems. More specifically, the subject matter herein relates to management systems for monitoring and controlling energy storage systems, such as batteries.

### BACKGROUND

Renewable energy sources such as solar energy and wind power, essential in combatting climate change, depend heavily on battery technologies in many instances. Such energy storage systems (ESS) are central to ensuring a stable and resilient power supply from intermittent renewable sources. However, such energy storage systems often face safety, performance, and flexibility concerns.

One example that is enabling the sustainable transition to renewable resources is electric vehicles (EVs), which have emerged as a prime solution to address one of the largest sources of climate pollution. The technology associated with energy storage systems, such as batteries, have become a cornerstone of electrification of transportation and hundreds of billions of dollars have been put into battery chemistry related research and development. Yet, instances of battery fires and EV recalls continue to cast a spotlight on suboptimal safety and performance issues in the industry.

A key part of the safety, performance, and flexibility of these various energy storage systems are the subsystems that provide management and control. For example, Battery Management Systems (BMSs) are critical components in modern energy storage and electric vehicle systems, playing a pivotal role in ensuring the optimal performance, safety, and longevity of rechargeable batteries. At its core, a BMS is an electronic system that monitors and manages the key parameters of a battery pack, and by continuously collecting and analyzing data from the cells within the battery, the BMS can, for example, make real-time decisions to balance the charge among cells, prevent overcharging or over-discharging, and regulate temperature to avoid thermal issues.

### SUMMARY

The subject matter described herein addresses many of the disadvantages associated with prior energy management systems by providing management systems at the cell level, instead of the system level. For example, unlike prior battery management systems that simultaneously process information from numerous battery cells and control all of those energy storage cells from a single BMS unit, in some aspects, the systems and methods described herein provide individual BMS units associated with each energy storage cell. In this manner, rather than being passive containers of chemicals, each battery cell may become a “smart” battery cell capable of actively reading, monitoring, and controlling the flow of energy, and the need for a central BMS system may be eliminated. Each single-cell BMS unit may further have bilateral communication capabilities with the other single-cell BMS units within the same battery pack, which may allow for more-sophisticated monitoring and control, increased device intelligence, more precise and real-time measurement of state of charge (“SOC”) and state of health (“SOH”), optimized safety, increased reliability and redundancy, and improved performance and flexibility, among other advantages. Under this new management electronics design, battery cells are no longer passive containers of chemicals that only produce energy, but are also actively reading, monitoring, and controlling the flow of energy and bilaterally communicating between the cells to exponentially increase safety, performance and flexibility. As another potential advantage, unlike many prior systems that lack the ability to measure the SoC and SoH of a specific cell in a battery pack in operation, the single-cell BMS in the systems and methods described herein may also accommodate sensors that measure internal changes in the connected cell that affect SoC and SoH, thereby allowing for real-time monitoring of SoC and SoH and improved detection time and accuracy.

This distributed, single-cell BMS arrangement also allows for unique battery arrangements and functionality which may not be easily implemented using traditional BMS designs. For instance, because each battery cell and single-cell BMS unit may effectively operate as a stand-alone unit, a modular approach may be easily taken when designing a new battery system. In particular, and for example, because each single-cell BMS system may be preprogrammed for combination with various battery constructions and chemistries, a system designer may easily combine any suitable number of battery cell units with one another, including if such units have different voltages, energy capacities, and/or chemistries. Furthermore, because each single-cell BMS may control the circuitry connecting each individual battery cell, unique circuitry control can provide extended battery life, charging flexibility, and improved safety (e.g., by simultaneously disconnecting each individual cell). Additionally, the close proximity of the single-cell BMS system to the individual cell may improve precision when monitoring battery cell variables, helping to reduce the noise of the system. The single-cell BMS may also advantageously receive information from other connected single cell BMSs and utilize artificial intelligence algorithms to process said information to further improve cell control, performance, and recognition of safety events.

In one aspect, the present disclosure provides a battery system. The battery system may include a first battery cell in a battery pack and a first battery management system (BMS) in communication with the first battery cell. The first BMS may include a first controller configured to receive measurement data for the first battery cell, to process the first battery cell measurement data, and to produce a control signal based on the processed measurement data from the first battery cell. The battery system may also include a second battery cell in the battery pack, and a second BMS in communication with the second battery cell. The second BMS may include a second controller configured to receive measurement data for the second battery cell, to process the second battery cell measurement data, and to produce a control signal based on the processed measurement data from the second battery cell.

In another aspect, the present disclosure provides a battery system. The battery system may include a first battery management system (BMS) including first switching circuitry configured to control the connectivity of a first battery cell in a battery pack. The battery system may also include a second BMS including second switching circuitry configured to control the connectivity of a second battery cell in the battery pack.

In yet another aspect, the present disclosure provides a battery unit. The battery unit may include a battery cell and a housing enclosing the battery cell. The housing may be configured to provide electrical access between the battery cell and at least one battery cell not contained within the housing. The battery unit may also include a battery management system (BMS) coupled to the enclosure and in communication with the battery cell. The BMS may include a controller configured to receive measurement data for the battery cell, to process the battery cell measurement data, and to produce a control signal based on the processed measurement data from the battery cell.

The details of one or more variations of the subject matter described herein are set forth in the accompanying drawings and the description below. Other features and advantages of the subject matter described herein will be apparent from the description and drawings, and from the claims.

### DESCRIPTION OF DRAWINGS

FIG. 1A illustrates a battery system including three battery cells connected in circuit and three respective battery management systems, in accordance with one aspect of the present disclosure.

FIG. 1B illustrates the battery system of FIG. 1A with the internal circuitry and components of each of the three respective battery management systems shown in greater detail.

FIG. 2 illustrates a section of a battery system including a battery cell and an associated battery management system, in accordance with one aspect of the present disclosure.

FIG. 3A illustrates a battery cell and switching circuitry of a battery management system associated with the battery cell, in accordance with one aspect of the present disclosure.

FIG. 3B illustrates the battery cell and switching circuitry of FIG. 3A shown operating in duty cycle control, in accordance with one aspect of the present disclosure.

FIG. 4 illustrates various operating modes for switching circuitry of a battery management system, in accordance with one aspect of the present disclosure.

FIG. 5 illustrates a controller of a battery management system, in accordance with one aspect of the present disclosure.

FIG. 6A illustrates various connection types for bi-directional communication interfaces of battery management systems, in accordance with aspects of the present disclosure.

FIG. 6B illustrates a wired, parallel connection, in accordance with aspects of the present disclosure.

FIG. 6C illustrates a wireless connection, in accordance with aspects of the present disclosure.

FIG. 7 illustrates various multi-cell arrangements associated with battery management systems, in accordance with aspects of the present disclosure.

FIG. 8 illustrates a battery unit, in accordance with one aspect of the present disclosure.

FIG. 9A illustrates a battery system having multiple battery cell chemistries and capacities in a fully charged state, in accordance with one aspect of the present disclosure.

FIG. 9B illustrates the battery system of FIG. 9A in a partially discharged state, in accordance with one aspect of the present disclosure.

FIG. 9C illustrates the battery system of FIGS. 9A-9B in a partially charged state, in accordance with one aspect of the present disclosure.

FIG. 10A illustrates a battery system having been fully charged from an 800V charger, in accordance with one aspect of the present disclosure.

FIG. 10B illustrates the battery system of FIG. 10A connected to a 400V charger, with half of the battery cells fully charged and the other half fully discharged and being bypassed in the circuit, in accordance with one aspect of the present disclosure.

FIG. 11 illustrates a method of controlling a battery system, in accordance with one aspect of the present disclosure.

FIG. 12 illustrates a method of charging a battery system, in accordance with one aspect of the present disclosure.

FIG. 13 illustrates a method of manufacturing a battery system, in accordance with one aspect of the present disclosure, in accordance with one aspect of the present disclosure.

The current subject matter will be better understood by reference to the following detailed description when considered in combination with the accompanying drawings which form part of the present specification.

### DETAILED DESCRIPTION

As used herein, “battery pack” may generally refer to at least two battery cells electrically connected in a series, parallel or a mixture of both, unless context dictates otherwise. The individual battery cells may be connected using a battery pack circuit that may be in electrical connection with, and configured to provide power to a device (e.g., an electric vehicle). As used herein, “battery circuit” may generally refer to a single battery cell electrically connected with a single battery management system, unless context dictates otherwise. Accordingly, a “battery pack” as used herein may include multiple battery cells in electrical connection with one another, with each battery cell potentially being a part of its own individual battery circuit with an associated battery management system.

As explained above, many commercial energy systems, such as batteries, rely on management systems for safety and control. Typical battery management systems (BMSs) are designed at a system or “pack” level, with long wire connections between a single central processing unit and sensor components, which may be placed on the battery cells. In other words, the BMS functions as a central hub, providing monitoring and control of all of the battery cells simultaneously. The present disclosure recognizes that this typical arrangement comes with numerous disadvantages. For instance, the long wire connections can create complexity for BMS design, because they often create measurement accuracy issues due to the parasitic impedance in the wires and the noise sensitivity due to the wires (i.e., signal pickup generated by electrical field). These long-wire measurement latency and accuracy issues can often lead to serious safety problems. Furthermore, each BMS must be tailored to the specific type, quantity, and size of the battery pack that it is controlling, thereby preventing easy expansion or replacement of the battery pack arrangement without reconfiguring the BMS. Further still, typical BMS systems rely on high-level control operations of the battery cells, rather than cell-by-cell control, which makes bypassing an individual cell impracticable, even though this may be advantageous in several situations.

The present disclosure recognizes that these disadvantages, along with the intricacies of battery behavior, diverse chemistries, and varying usage patterns, demand more sophisticated monitoring and controls, increased device intelligence and more precise measurement of state of charge (“SOC”) and state of health (“SOH”). Accordingly, the present disclosure provides systems and methods related to energy management systems (e.g., BMSs) that function at a cell level (e.g., a battery cell), providing improved monitoring and control of the cells, as well as providing additional functional advantages to the overall system that would otherwise not be possible if relying on a centralized BMS. In other words, each cell is transformed into a “smart” energy storage vessel that actively reads, monitors and controls the flow of energy.

While the systems and methods described herein are primarily discussed as examples of battery management systems, it should readily be appreciated that the teachings described herein can be applied to any suitable energy storage system, including, but not limited to, capacitors, supercapacitors, fuel cells, as well as other energy systems that may benefit from localized control of the energy cells in use. Furthermore, it should also be appreciated that the systems and methods of the present disclosure allow for various combinations of these energy storage systems (e.g., a supercapacitor in circuit with a battery cell).

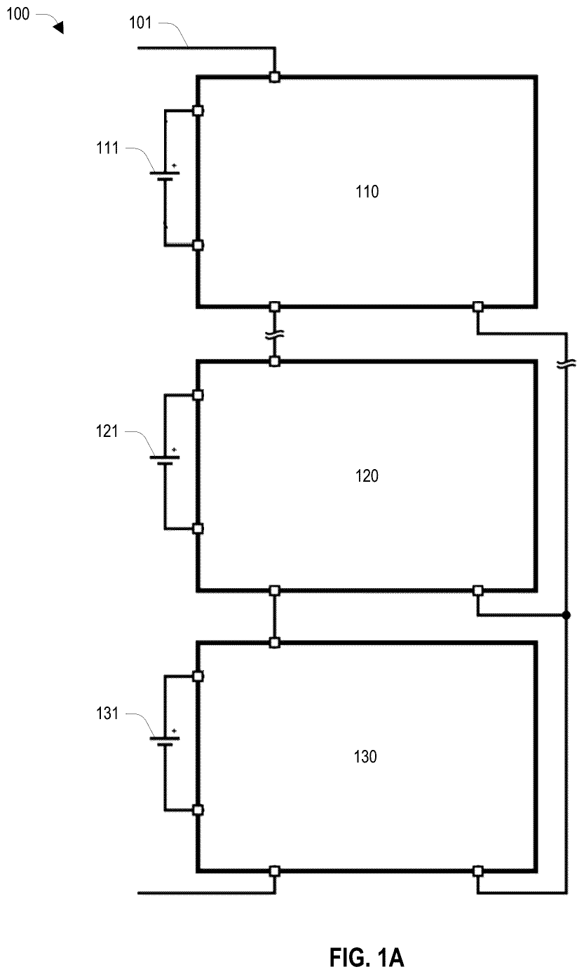

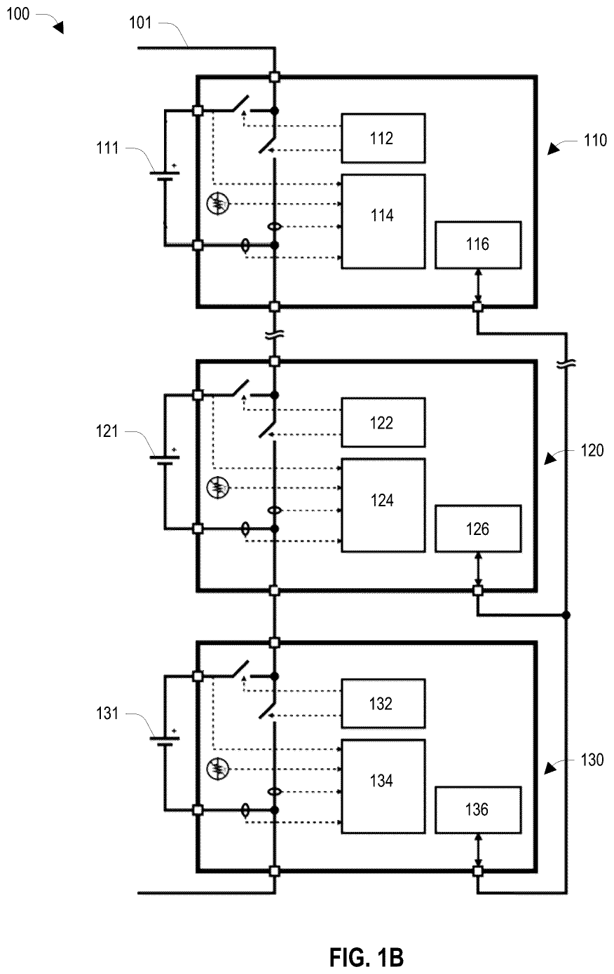

FIG. 1A depicts a battery system 100 including three battery cells 111, 121, 131, which are all electrically connected in a circuit 101 of a battery pack, and three respective battery management systems 110, 120, 130. The first BMS 110 may function to monitor and control the first battery cell 111, the second BMS 120 may function to monitor and control the second battery cell 121, and the third BMS 130 may function to monitor and control the third battery cell 131. In this manner, each battery cell 111, 121, 131 is provided with its own localized BMS system. The battery system may have positive and negative terminals, and may function to supply and receive electrical energy, as necessary. For instance, the battery pack circuit 101 may be configured to connect to an electrical load (e.g., an electric vehicle, a power grid, a residential home, etc.) and may be configured to supply electrical output energy. Likewise, the battery cells 111, 121, 131 may be rechargeable, and the battery pack circuit 101 may be configured to connect to a charger source, which may supply electric energy to the battery cells 111, 121, 131. While the three battery cells 111, 121, 131 are connected in series in this depiction, it should be readily appreciated that various additional circuit arrangements may be utilized with any suitable number of battery cells and respective BMSs.

FIG. 1B depicts the battery system 100 of FIG. 1A with the internal circuitry and components of each BMS 110, 120, 130 shown in greater detail. As will be further described, each of the BMSs 110, 120, 130 may include various components for monitoring and controlling the battery cells 111, 121, 131. For instance, each BMS 110, 120, 130 may include a controller 114, 124, 134, switching circuitry 112, 122, 132, and a communication interface 116, 126, 136, the functionality of each of which is further described herein.

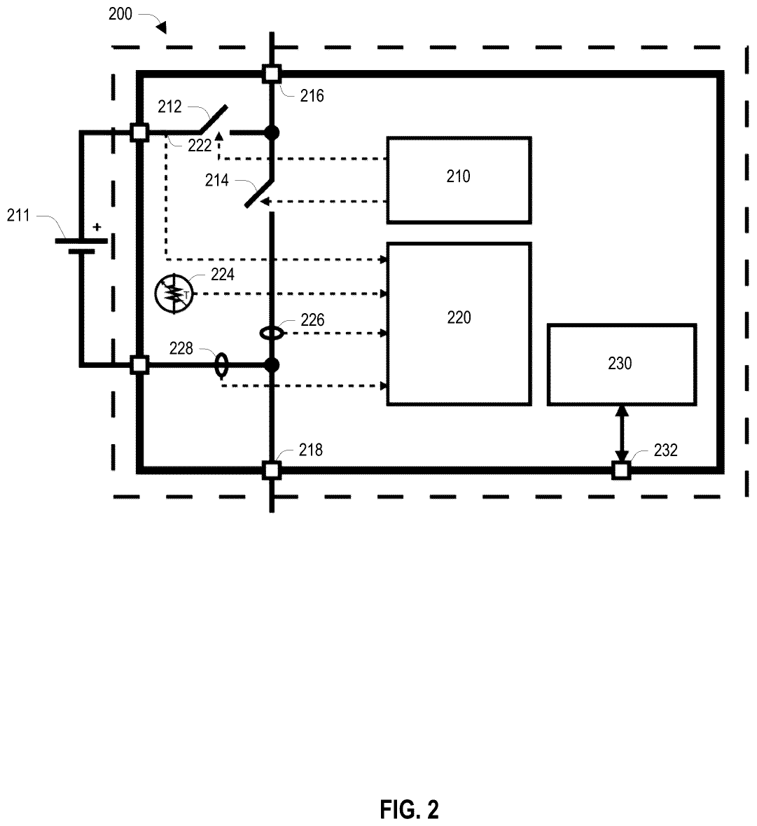

FIG. 2 depicts a section of a battery system including a battery cell 211 and an associated battery management system 200 (contained within the dashed lines in this depiction). The battery management system 200 may include a positive terminal 216 and a negative terminal 218 as part of the electrical circuit to which the battery cell 211 may be connected to. The BMS 200 may include various components, including but not limited to, switching circuitry, which may include a switch controller 210 configured to adjust a cell switch 212 and a bypass switch 214. The switching circuitry may be configured to safely connect, disconnect, bypass, short, and/or partially connect the battery cell during operation. A cell controller 220 may be in electrical communication with the switch controller 210 and configured to receive measurement data for the battery cell 211. This data may be provided to the cell controller 220 using a number of sensor components. For example, as shown, a voltage sensor 222, temperature sensor 224, and multiple current sensors 226, 228 may all supply measurement data to the controller 220 to permit active monitoring of the battery cell 211. Among other advantages, the in-situ measurement (sensing) architecture of the BMS 200 may provide better detection of the early signs of battery degradation and failure while increasing performance, reliability, and safety. The controller 220 may be configured to process the first battery cell 211 measurement data and to take certain actions depending on these inputs, including producing a control signal that may be provided to the switch controller 210 in order to modify the state of switches 212, 214 (e.g., to open or close one switch, or both). The BMS may also include a bi-directional communication interface (BCI) 230 in electrical communication with the cell controller 220 and the switching circuitry. The BCI may be configured to provide and receive communication signals to other BMSs, to internal battery system components, or to external systems. In this depiction, the BCI 230 may rely on a communication port 232 when providing communication signals to other BMSs.

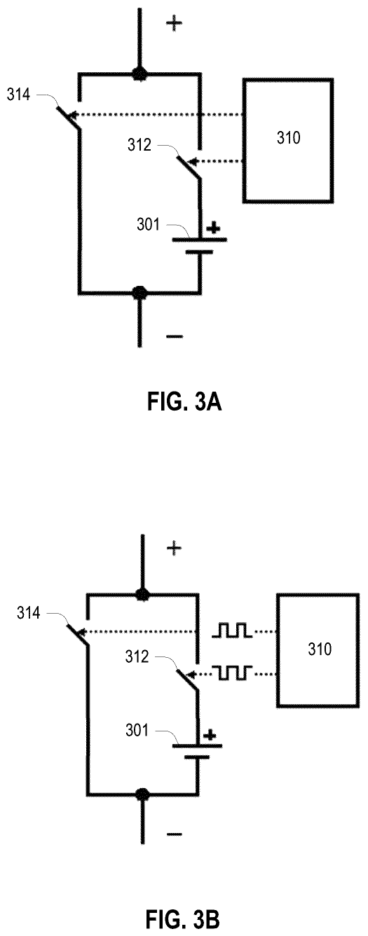

FIG. 3A-B depict a battery cell and switching circuitry of a battery management system associated with the battery cell in various arrangements, including undergoing duty cycling (FIG. 3B). Generally, the switch controller 310 may be configured to connect and disconnect the battery cell 301 from the battery pack (i.e., from the battery pack circuit used to supply electrical energy to a connected device or system). The switch controller 310, may modify the connections to the battery cell 301 upon receiving control signals, such as signals provided from a BMS (not depicted) based on the processed battery cell measurement data. For instance, a controller of a BMS system may be configured to process battery cell measurement data to determine if the battery cell 301 is experiencing a hazardous condition and to provide a control signal to the switch controller 310 only if the first battery cell is indeed experiencing such a hazardous condition. Using this localized switching circuitry, the battery cell 301 may be isolated from the battery pack circuit (i.e., the circuit may bypass the battery cell 301 but otherwise function normally), or the circuit may be entirely disconnected, depending on the control signal received by the switch controller 310. In order to achieve this functionality, the switching circuitry may include both a cell switch 312 configured to control the electrical connection between the first battery cell 301 and the battery pack circuit, and also a bypass switch 314 configured to control the electrical connection on an electrical pathway of the battery pack circuit bypassing the first battery cell. Although not depicted in FIGS. 3A-B, it should be readily appreciated that the cell switch 312 may be alternatively positioned on the negative terminal side of battery cell 301. Likewise, although the cell switch 312 and the bypass switch 314 are shown depicted on the individual battery circuit connecting the battery cell 301 to the BMS, it should be appreciated that these components may be alternatively positioned elsewhere, provided a similar functionality is achieved.

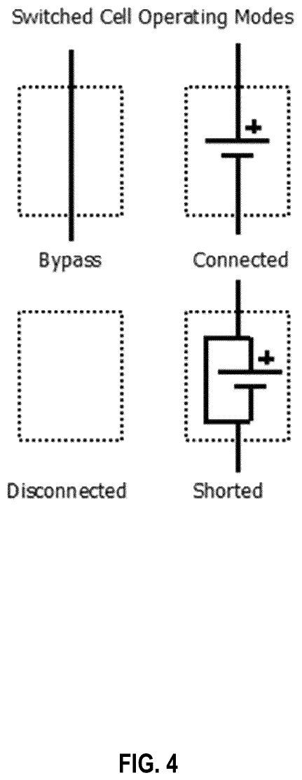

FIG. 4 depicts various operating modes for switching circuitry of a battery management system. As shown, the switching circuitry may be configured to connect (cell switch closed, bypass switch open), bypass (cell switch open, bypass switch closed), short (cell switch closed, bypass switch closed), and/or disconnect (cell switch open, bypass switch open) the battery cell. As will be further described, this localized switching circuitry control can provide numerous safety and performance advantages to the overall battery system. For example, active balancing of the battery cell may be monitored and controlled using the cell controller and may be performed either when charging or discharging the battery cell, simply by actively adjusting the switching circuitry. This balancing may improve the charging rate and the maximum energy storage of the battery cell, while also minimizing capacity mismatching and minimizing charge cycle during operation. Likewise, when the battery pack is not in use, each of the battery cells may be disconnected from one another at a local level (rather than simply disconnecting one section of the overall circuit) which may help to prevent and contain hazardous battery events (e.g., unattended fire). Further still, if a battery cell is determined to be faulty (i.e., no longer functional), the switching circuitry may allow for the cell to be simply bypassed, while still permitting the use of other functioning cells within the battery system. Any suitable electrical switching circuit components may be employed to provide this functionality. Furthermore, it should be appreciated that other switching circuitry arrangements beyond these examples may be used to provide this localized control.

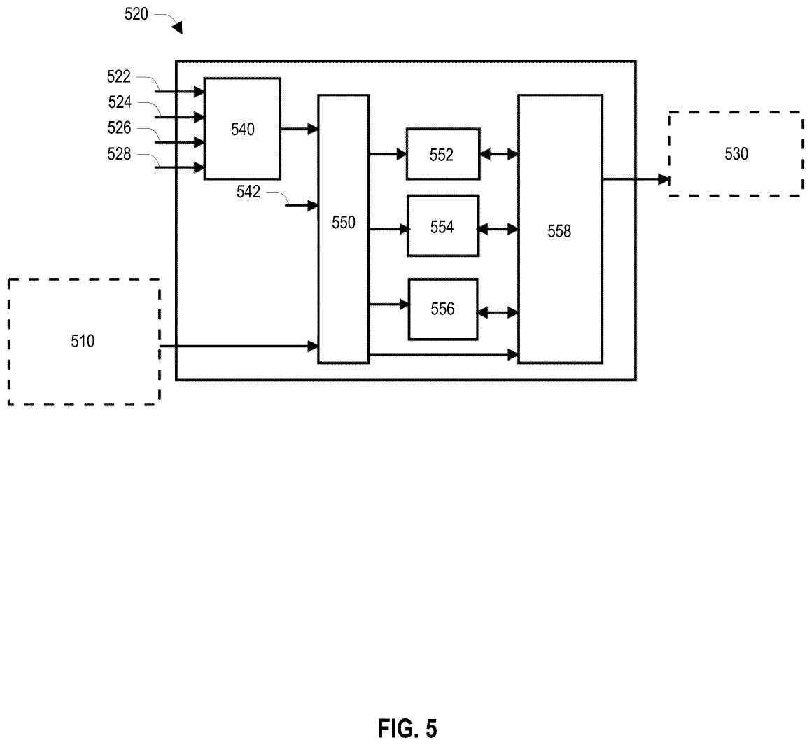

FIG. 5 depicts a cell controller 520 of a battery management system. The controller 520 may include various components which allow for functionality such as receiving measurement data (i.e., cell telemetry) from cell sensors, processing this measurement data, storing this processed measurement data, communicating this measurement data to other BMSs, and providing control signals to switch circuitry or other BMSs. In this manner, the cell controller 520 may function as the “brain” of the local BMS, allowing for real time processing and control of the battery cell.

As shown, the cell controller 520 may receive various inputs, including measurement data for local cell voltage 522, local cell temperature 524, local cell current 526, as well as other local cell data 528 (e.g., data from one or more additional sensors). This measurement data may be received as signals at a telemetry monitor 540. The telemetry monitor 540 may accurately collect analog and digital information from the battery cell that the BMS is associated with and digitize the collected information (e.g., using an analog-to-digital converter (ADC) and internal voltage reference to convert the cell voltage, cell charge/discharge current, and temperature). Next, the telemetry monitor 540 may transfer the digitized information to different functional sections within the cell controller 520.

A data interface 550 may be used to transfer the information from adjacent (or all) BMSs in the battery system to different functional sections within the controller 520 of the individual BMS. For example, the data interface 550 may receive information 510 from the bi-directional communication interface of the individual BMS, including, but not limited to, cell measurement data and status information from other BMSs in the battery system, cell ID/authentication data from other BMSs in the battery system, and cell state of health (SoH) and state of charge (SoC) from other BMSs in the battery system. Additionally, the data interface may receive characteristic information of the other battery cells in the battery system, such as cell characteristic curves, cell allowable operating ranges, cell ID/serial numbers, and cell chemistry types.

The controller 520 may include various processing sections (contained within one or more microprocessors or microcontrollers) that may rely on algorithms to determine SoH and SoC of the local battery cell based on information provided by telemetry monitor 540, data interface 550, a cell history memory storage 554 and system memory 556 within the controller. For example, the SoC and SoH computation 552 may be based on (but is not necessarily limited to) variables such as the cell voltage, cell current, coulomb counting (during charging or discharging), temperature, extracted impedance, cell history, hysteretic behavior, and cell parameters and characteristic transfer functions published by the battery cell manufacturer (i.e., SoC and SoH flowchart) of the local battery cell. The SoC and SoH of other battery cells within the battery system may also be determined by the controller 520 based on information provided by other BMSs, which may allow for improved redundancy and confirmation of any SoC or SoH calculation by other BMSs.

The cell history memory storage 554 may be configured to store and track information about the local battery cell of the BMS that the controller 520 is associated with. The cell history memory storage 554 may store information such as battery chemistry type, battery identification number, cell capacity, change in cell capacity over time, timestamps of charge or discharge activities with coulomb counting (charge/discharge current and duration) and state of charge information, maximum/typical/minimum cell voltages and cell temperature and cell charge/discharge current, cell impedance and maximum power delivery, start of service (formation timestamp), charge cycle count, state of charge and state of health history, of the local battery cell.

The data contained within the cell history memory storage 554 may be used to increase the predictability of the life of the overall battery system as well as the local battery cell by comparing cell history data of other BMSs (therefore all the cells) in the stack. The data contained within the cell memory storage 554 and/or the system memory 556 may continue to adaptively increase its accuracy as more data is collected and updated iteratively by the controller 520. For example, the information in the cell history memory storage 554 is used along with the latest updated SoC and SoH computations to continuously update BMS control and operation. The system memory 556 may function as a general storage of information measured, transferred, computed, processed, and/or generated by the BMS. For instance, SoC/SoH computation results and storage of memory to support embedded software/firmware are examples of items that may be stored in general system memory 556. The cell history memory storage 554 may contain information regarding the characteristics of the local memory cell, such as its cell characteristic curve, its allowable operating ranges, its capacity, its cell ID/serial number, and its cell chemistry type.

Embedded Software/Firmware processing (ESP) 558 may be used to extract, compute, and process the information within the individual BMS. The main function of the ESP 558 may to keep the BMS operation safe and reliable. The ESP 558 can be iteratively modified by ESP programming for optimal operation such as switching circuitry control, as described above, or the ESP 558 may operate autonomously without user intervention to protect the BMS from various fault (i.e., instant failure) or potential fault conditions (i.e., slow failure). The ESP 558 may be designed to continuously identify, monitor, and update charge capacity, charge status, and cell history of the local battery cell (including cell SoC and SOH).

As described above, the controller 520 may be configured to continuously monitor cell parameters for indication of degradation or patterns to prevent further degradation (i.e., improve SOH) or catastrophic failure (for example, thermal runaway due to elevated impedance). In other words, the controller 520 may use the processed cell measurement data, the cell history data, and the measurement and cell history data provided by other BMSs to produce various command signals that may be provided to switching circuitry 530. For example, the controller 520 may be configured to determine if the temperature range or operating voltage range of the local battery cell has been exceeded, and if so, to produce a control signal to either (i) disconnect the first battery cell in a manner that the battery pack circuit bypasses the first battery cell, or (ii) disconnect the entire battery pack circuit. In some aspects, the controller 520 may also provide communication signals to the switching circuitry of other BMSs or to external devices (e.g., a car management system, a personal communication device such as a cellphone or tablet, etc.). For instance, in the event that the controller 520 determines that the battery cell is approaching a hazardous condition (e.g., an increasingly excessive temperature is measured), the controller 520 not only instruct the switching circuitry to disconnect the entire battery pack circuit, but may also provide a communication signal to other BMSs instructing them to open their respective switching circuitry, which may help to contain the hazardous condition.

The controller 520 may utilize intelligent monitoring and control of the battery cell, in order to maximize the usable capacity of the battery, optimize charging and discharging rates, minimizing the number of battery charge cycles to extend the overall lifespan of the battery cell. Accordingly, the controller may utilize artificial intelligence at the cell level, such as machine learning and/or deep learning algorithms when processing the measurement data. For instance, the controller 520 may employ a machine learning algorithm to predict whether the first battery cell will likely experience a hazardous condition (e.g., thermal runaway), based on the current and past measurement data of the local cell, the other cells in the battery system, as well as pre-programmed information relating to various hazardous conditions. Likewise, similar algorithms may be utilized to provide more-accurate SoC and SoH calculations, utilizing accurate real time measurements of the cell parameters, operation conditions, and changes in the battery cell as a result of charging or discharging cycles. Moreover, machine learning algorithms may be used to accurately determine instantaneous output power calculation, which may be based on, for example, cell voltage, state of charge, temperature, charge direction (charging or discharging), and impedance (both DC and AC equivalent).

As previously described, one of the advantages of the BMS systems described herein is safety enhancement. The BMS systems described herein may achieves this by implementing various protective mechanisms at the local level of each battery cell, such as overvoltage and undervoltage protection, overcurrent protection, and thermal management. In the event of a fault or abnormal condition, the BMS can trigger safety measures, including disconnecting the battery cell from the load or charging source, to prevent potential hazards like overheating or fires. This safety aspect is particularly crucial in applications where large battery packs are used, such as electric vehicles, stationary energy storage systems, and renewable energy installations. Furthermore, each local battery cell may be disconnected whenever not in use, such as when the connected system is in a standby or off mode (e.g., an electric vehicle parked in the garage). Utilizing local switching circuitry, an individual battery cell in a battery stack may be disconnected in safety critical conditions, and may also be bypassed for safety. This localized control may also help to extend battery-pack run time or battery-pack life time, or advantageously permit partial connection or short for cell balancing, conditioning, and/or temperature balancing. In typical BMS designs, changing battery stack arrangement during BMS operation is either impracticable or adds undesirable complexity to the BMS design. However, in some of the aspects described herein, a battery cell may be swapped out in real time by simply locally bypassing the original battery cell being replaced.

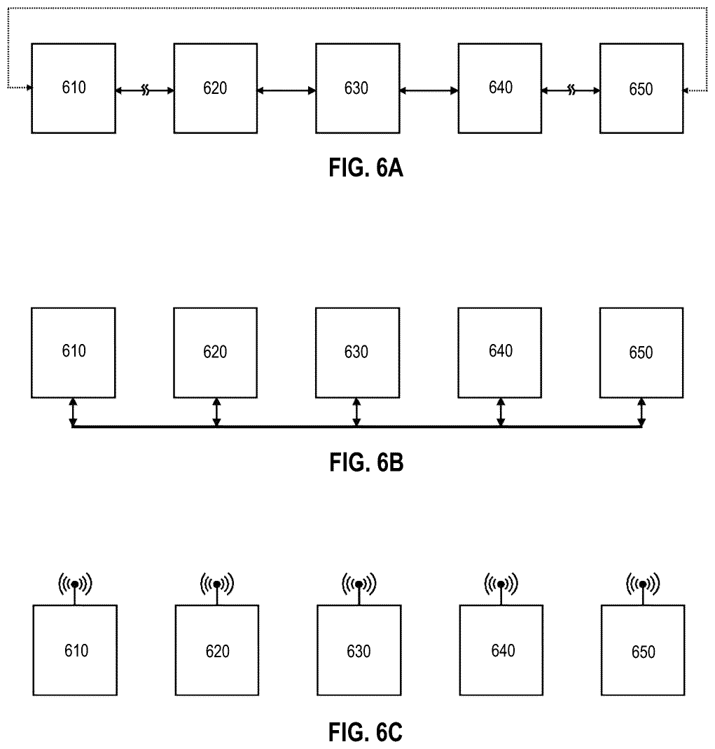

FIG. 6A depict various connection types for the bi-directional communication interfaces of battery management systems 610, 620, 630, 640, 650. Specifically, FIG. 6A depicts a wired, daisy-chained connection of the BCIs, with an optional redundant pathway shown between a first BMS 610 and a fifth BMS 650. FIG. 6B depicts a wired, parallel connection of the BCIs. FIG. 6C depicts wireless connection of the BCIs. Other possible connection types, or combinations of the types depicted, may be used to permit communication between the various BMS described herein. The BCI may be configured to seamlessly connect BMSs within the battery system, creating a two-way information network between all battery units (or modules). As described, once the connection is made with another BCI within the battery system, the BCI may be configured to transfer battery cell information that is stored and/or generated within each BMS. Examples of the transferable battery cell information include, for example, cell voltage, cell current, cell capacity, cell temperature, stored cell history data, faults, embedded algorithms, timestamps, switching circuitry control commands, and cell identifier/authentication, which may be used to prevent unauthorized BMS access.

The cell-to-cell communication provided by the BCI associated with each BMS may be used as a redundant verification solution in the battery stack design. Using the BCI, cell information, such as that obtained from the cell controller of each BMS in the battery system may be exchanged, shared, and verified by every BMS in the battery system, thereby providing redundancy for the cell parameter measurements, switching circuitry status and control, calculated data, faults, battery cell history data, SoC/SoH computation data, system memory data, hysteretic behavior, and/or cell ID/authentication. In typical BMS designs adding such redundant verification is difficult due to circuit complexity, cost, and size. By allowing for every BMS in the battery system to function as a verification solution, improvements to overall safety, reliability, and performance may be achieved.

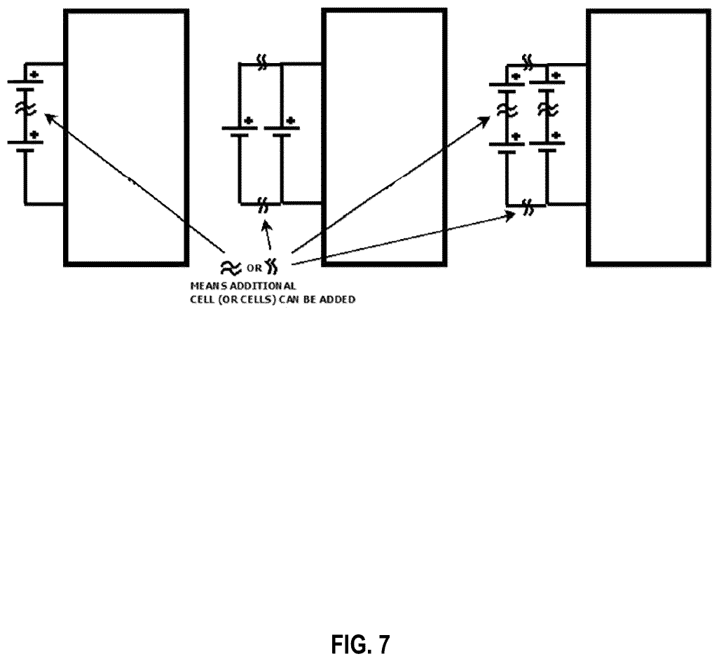

While many examples of the present disclosure have a single battery cell associated with each BMS, it should be appreciated that other arrangements are possible. For instance, FIG. 7 depicts various multi-cell arrangements associated with three different BMS systems (represented by boxes). As shown, the BMSs may each control multiple battery cells simultaneously, and the battery cells may be connected in series, in parallel, of a combination thereof. In doing so, the BMS may effectively treat this combination of battery cells as a single collective battery cell. For instance, the switching circuitry and/or the cell sensors may be collectively attributed to each multi-cell grouping (i.e., each individual cell could not be bypassed, but the multi-cell group could be bypassed together). It should also be appreciated that other variations on the systems described herein may be possible, such as including select components (e.g., system memory) on only some of the BMSs or external to the battery system and relying on bi-directional communication between the various BMSs to access the functionality of these select components.

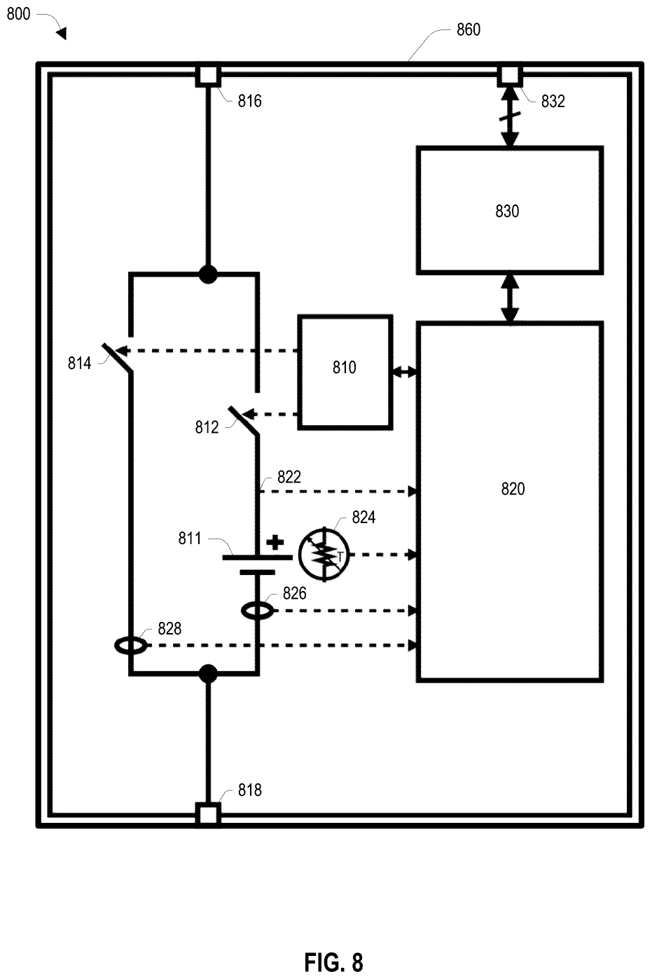

FIG. 8 depicts a battery unit 800 configured to be incorporated into a battery system, which may incorporate any of the teachings previously described herein for BMSs. As shown, the battery unit 800 may include a battery cell 811 enclosed within a housing 860. Coupled to the housing 860 are various components forming a BMS may be in electrical communication with the battery cell 811, including switching circuitry (switch controller 810, cell switch 812, and bypass switch 814), a bi-directional communication interface 830, and a cell controller 820. The controller 820 may be connected to a number of sensors surrounding the cell, including a voltage sensor 822, a temperature sensor 824, and multiple current sensors 826, 828. Although depicted as enclosed within the housing 860, alternative arrangements of the BMS are possible, including such as being attached to an exterior surface of the housing 860.

The housing 860 may be configured to provide electrical access between the battery cell 811 and at least one battery cell not contained within the housing 860. In order to facilitate this connection, the housing 860 may include electrical ports 816, 818 configured to provide electrical access between the battery cell 811 and any battery cells not contained within the housing 860. Similarly, the housing 860 may be configured to provide electrical access between the bi-directional communication interface 830 and other BMSs that may be connected to the battery unit 800. Consistent with the localized control of battery cells described herein, the housing 860 may specifically enclose no additional battery cells configured to be connected with the battery cell 811. Similarly, the housing 860 may specifically enclose only a single composite cell, as previously described with reference to FIG. 7.

Advantageously, the distance separating the controller 820 and the battery cell 811 may be reduced by the BMS's close proximity to the battery cell 811. Specifically, the controller 520 or the BMS may be less than the maximum width of the battery cell 811, or more specifically less than one half of the maximum width of the battery cell 811. The controller 820 may be directly integrated with a terminal of the battery cell 811, such that no wires are used to connect these two components. As previously described, by integrating the BMS directly with the battery cell 811 in the battery unit 800, the length of the wire connection between the BMS and the battery cell 811 is significantly reduced and therefore more precise measurements may be produced with minimal latency. The low latency may equate to substantially better fault response, improved SoC and SoH calculation accuracy and parasitic impedance calculation. Thus, the voltage drop and noise interference associated with long wires and error-prone connectors may be avoided using this integrated battery unit construction. Additionally, this flexible battery pack assembly architecture may enable simple “building block” assembly of battery packs and also may permit individual cells in the battery pack to be serviceable, significantly reducing cost of ownership and increasing battery life.

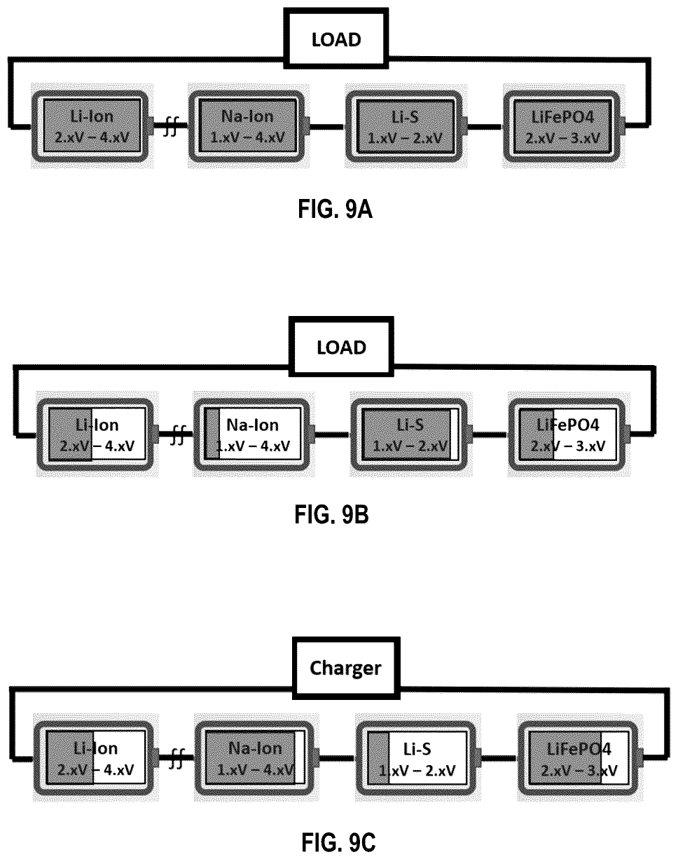

FIGS. 9A-9C depict a battery system with localized BMSs having multiple battery cell chemistries (Li-Ion, Na-Ion, Li—S, LiFePO₄) and capacities in a fully charged state. Because some aspects of the systems and methods described herein permit local control over each battery cell, multi-chemistry systems such as this may be easily constructed, controlled, charged, and discharged. Given that various battery chemistries are particularly suitable for specific discharging and charging applications, the ability to continue to use functional cells, while bypassing other cells in the circuit, may be quite advantageous. For example, FIG. 9B depicts the battery system of FIG. 9A in a partially discharged state, with the Li—S battery yet to be substantially depleted. As shown in the example, different cell chemistries discharge at different rates at various float voltages. The single-cell BMSs described herein accurately capture these differences and seamlessly generate proper controls that will discharge sodium-ion first (with the lowest energy density and lowest capacity) to its SoC limit; then the BMSs will continue to guide the battery to discharge the remaining cells in the order of its energy density. So, if discharging were to continue with this example, the BMS associated with the Na-Ion cell could control its switching circuitry to have this cell bypassed once it has fully depleted its operating range, while the Li—S battery cell continues to discharge in the circuit. Likewise, FIG. 9C depicts the battery system in a partially charged state; once the Na-Ion cell is fully charged, the BMS may ensure that this cell is bypassed while other cells completed charging.

As described, because the BMSs of each battery cell may be configured to communicate cell characteristic information to one another (e.g., number of cells, capacity, chemistry type, etc.), each BMS may be configured to determine the overall structure and performance of the battery system, including its overall operating ranges and actual usable capacity. With this information, the controller may further self-configure and optimize SOC and SOH. The BMSs may be configured to perform these calculations immediately upon combination with a new BMS.

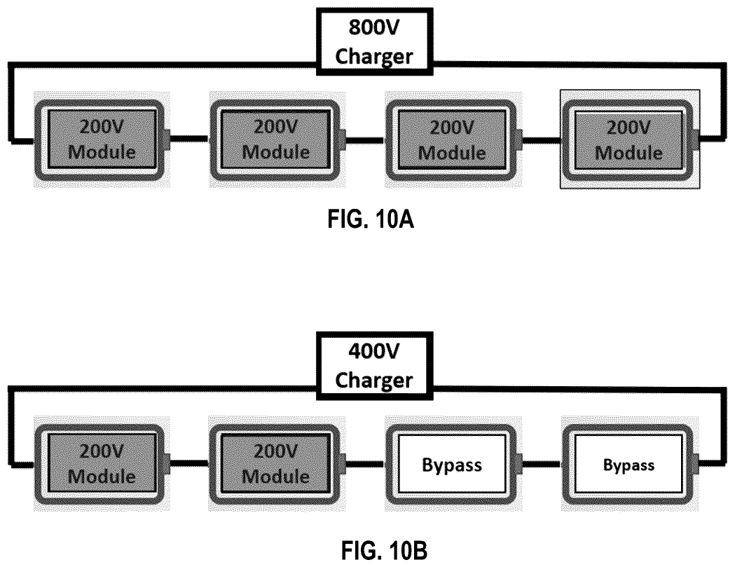

Furthermore, the BMSs may specifically communicate to adapt to different input charging voltages (e.g., 400V_{DC} vs. 800V_{DC}), thereby providing the battery system the ability to be compatible with different charging infrastructure types (i.e., a 800V_{DC} battery system can be charged at a 800V_{DC} or 400V_{DC} charging station). FIG. 10A depicts a battery system having been fully charged from an 800V charger. As with discharging, complex SoC calculation and safe end-of-charge termination may be achieved by the BMSs and their integrated switching circuitry (i.e., power path switches). The BMSs may detect the input voltage amplitude ranges during the initial handshake when charger cable is connected. Once input voltage amplitude is established, the BMSs may calculate battery stack voltage range (using bi-directional communication) to determine which cells are to be connected or bypassed. As shown in this example, because each of the four battery cells in this example are 200V cells, they may each be simultaneously charged using an 800V charger. However, FIG. 10B depicts the battery system of FIG. 10A connected to a 400V charger. With prior systems, charging this battery pack from this charger is generally impracticable without additional conversion equipment. But with the local bypassing control described herein, change in voltage of the battery system can also be achieved “virtually,” allowing the battery to be charged at different voltages. For instance, as shown, half of the battery cells may be fully charged with the other half fully discharged and being bypassed in the circuit and awaiting their turn to be charged. A same bypassing technique may be used to control the output voltage that is discharged by the battery. For instance, a portion of the battery cells contained within the battery system may be controllably discharged while other battery cells are not discharged, thereby allowing the system to provide different output voltages and to provide active cell balancing while discharging.

It should be readily appreciated that the systems and methods described herein may be applied to numerous battery chemistry types and, in fact, particularly enable the combination of different battery chemistry types in the same pack. For instance, a lithium ion battery cell may be selected with, for example, a second battery cell selected from the group consisting of a nickel-metal hydride battery cell, a lead-acid battery cell, and a sodium ion battery cell. In particular, the battery system may include battery cells that have different capacities from one another. As one example possibility, the high energy density of lithium-ion battery cells may be combined with a fast-charging capability of sodium-ion battery cells. Such mismatching chemistry and/or battery cell capacity is easily supported by standalone and independent control of each single-cell BMS.

The energy management systems described herein are applicable to energy systems beyond the battery management systems described. For instance, an energy storage system may include multiple energy storage cells (e.g. supercapacitor, fuel cell, etc.) and multiple energy storage management system (ESMS) in electrical communication with each energy storage cell. The ESMSs may each incorporate any of the teachings described herein relating to the BMSs of the battery system examples, including the use of a local, single-cell controller and local switching circuitry. In this manner, one could easily construct a system that combines the benefits of multiple different energy sources, such as by seamlessly integrating multiple battery cells with multiple supercapacitors. As with battery systems having different chemistries, the ESMSs may be configured to communicate to adapt to the addition of various new types of energy sources, and may contain preprogrammed software for identification and management of the various energy source combinations.

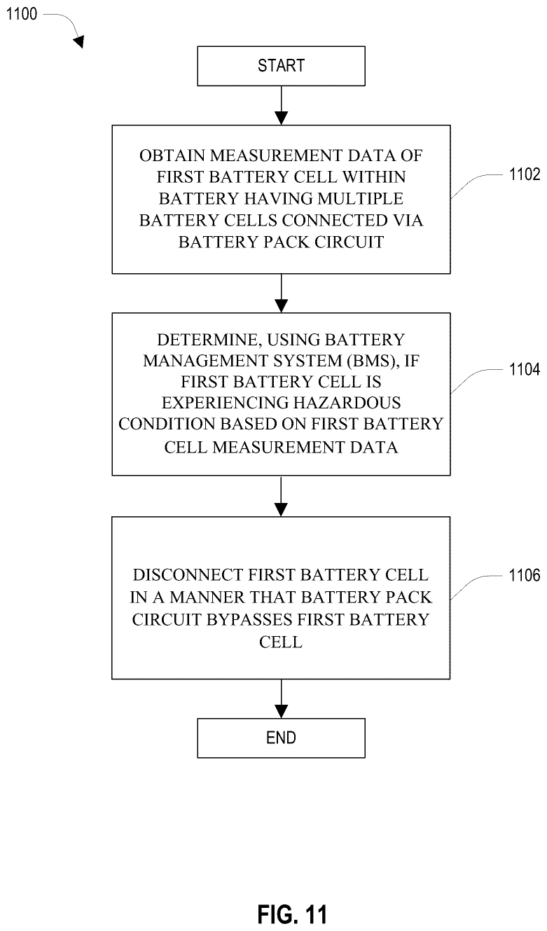

FIG. 11 depicts a method 1100 of controlling a battery system. At 1102, measurement data of a first battery cell within a battery having multiple battery cells connected via a battery pack circuit is obtained. Then, at 1104, it is determined, using a battery management system (BMS), whether the first battery cell is experiencing a hazardous condition based on the first battery cell measurement data. Finally, at 1106, the first battery cell is disconnected in a manner that the battery pack circuit bypasses the first battery cell. In other words, the method 1100 allows for the selective bypass of a single battery cell that is experiencing a hazardous condition (e.g., thermal runaway) based on measurement data (e.g., cell temperature readings). Beyond hazardous conditions, the method 1100 may also be applied to faulty battery conditions, such as when a battery cell is not functioning properly (e.g., providing no discharge).

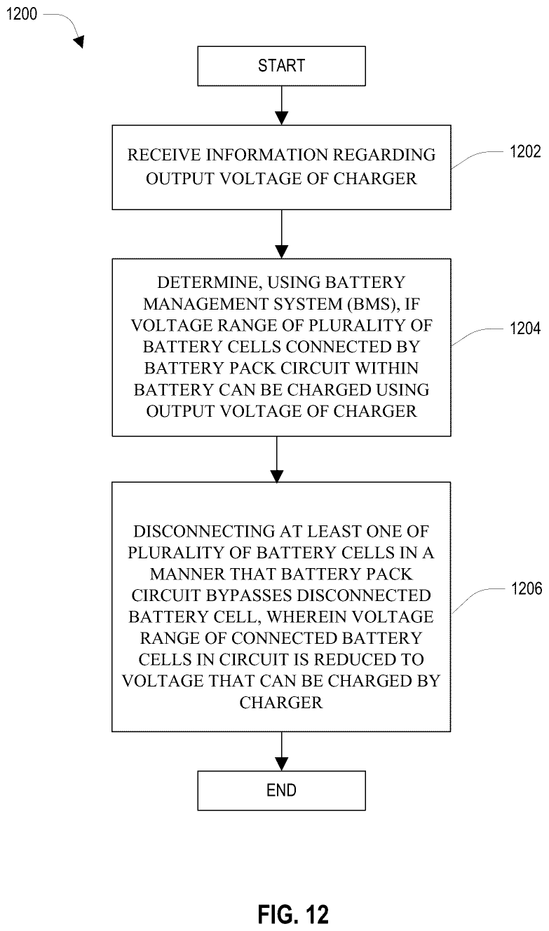

FIG. 12 depicts a method 1200 of charging a battery system. At 1202, information regarding an output voltage of a charger is received. At 1204, it is determined, using a battery management system (BMS), whether the voltage range of a plurality of battery cells connected in a battery pack can be charged using the output voltage of the charger. Finally, at 1206, at least one of the plurality of battery cells is disconnected in a manner that the battery pack circuit bypasses the at least one disconnected battery cell, wherein the voltage range of the connected battery cells in the circuit is reduced to a voltage that can be charged by the charger. Accordingly, this method allows for the selective charging of only a portion of the total number of battery cells within a battery system, and thereby expands the types of chargers that may charge the battery system.

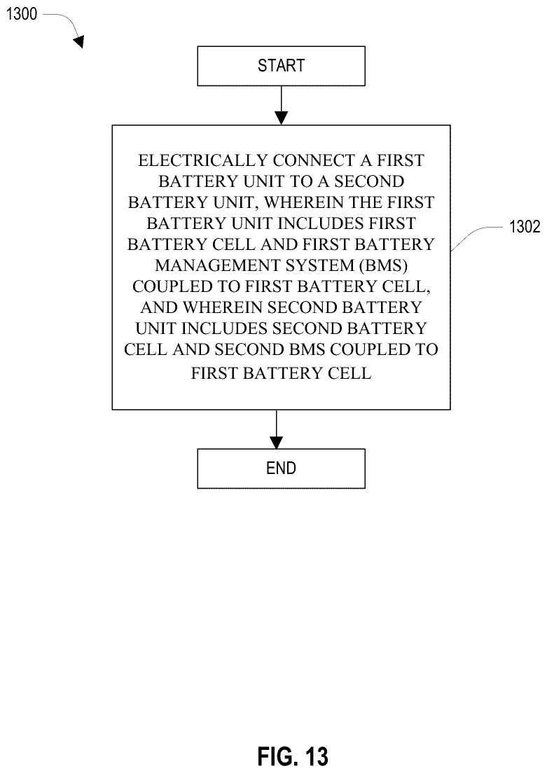

FIG. 13 illustrates a method 1300 of manufacturing a battery system. At 1202, a first battery unit is electrically connected to a second battery unit. The first battery unit may include a first battery cell and a first battery management system (BMS) coupled to the first battery cell, while the second battery unit may similarly include a second battery cell and a second BMS coupled to the first battery cell. In this manner, multiple battery units, each with their own respective BMS, may be easily combined using this method.

While traditional systems often require that a BMS be constructed tailored to the number and type of battery cells ultimately placed in the system, the method 1300 may allow for a “building block” assembly process, where each battery unit is simply connected together and limited further tailoring of the already-integrated BMSs is necessary.

In accordance with the above description, in one aspect, the present disclosure provides a battery system. The battery system may include a first battery cell in a battery pack and a first battery management system (BMS) in communication with the first battery cell. The first BMS may include a first controller configured to receive measurement data for the first battery cell, to process the first battery cell measurement data, and to produce a control signal based on the processed first battery cell measurement data. The battery system may also include a second battery cell in the battery pack, and a second BMS in communication with the second battery cell. The second BMS may include a second controller configured to receive measurement data for the second battery cell, to process the second battery cell measurement data, and to produce a control signal based on the processed second battery cell measurement data. The first controller may be configured to determine the state of charge and state of health of the first battery cell when processing the first battery cell measurement data, and the second controller may be configured to determine the state of charge and state of health of the second battery cell when processing the second battery cell measurement data. The first BMS may further include a first temperature sensor configured to measure the temperature of the first battery cell, and the first battery cell measurement data may include temperature data. Likewise, the second BMS may further include a second temperature sensor configured to measure the temperature of the second battery cell, and the second battery cell measurement data may include temperature data. The second controller may be configured to produce the control signal based on both the processed measurement data from the second battery cell and the temperature data measured by the temperature sensor of the first BMS.

The first BMS may further include a first voltage sensor configured to measure the voltage of the first battery cell, and the first battery cell measurement data may include voltage data. Similarly, the second BMS may further include a second voltage sensor configured to measure the voltage of the second battery cell, and the second battery cell measurement data may include voltage data. The first BMS may further include a first current sensor configured to measure the current of the first battery cell, and the first battery cell measurement data may include current data. Similarly, the second BMS may further include a second current sensor configured to measure the current of the second battery cell, and the second battery cell measurement data may include current data.

The first BMS may further include switching circuitry configured to disconnect the first battery cell from the battery pack. The switching circuitry may be configured to receive the control signal based on the first battery cell measurement data and to disconnect the first battery cell from the battery pack. Further, the first controller may be configured to process the first battery cell measurement data to determine if the first battery cell is experiencing a hazardous condition and to produce the control signal only if the first battery cell is experiencing a hazardous condition. The switching circuitry may include a cell switch configured to control the electrical connection between the first battery cell and the battery pack, and a bypass switch configured to control the electrical connection on an electrical pathway of the battery pack bypassing the first battery cell.

The first controller may include a first system memory configured to store the first battery cell measurement data (including both processed and/or unprocessed measurement data). Likewise, the second controller may include a second system memory configured to store the second battery cell measurement data (including both processed and/or unprocessed measurement data). The first system memory may store information regarding the temperature range and operating voltage range of the first battery cell. The first controller may be configured to determine if the temperature range or operating voltage range of the first battery cell has been exceeded and to produce the control signal to disconnect the first battery cell in a manner that the battery pack bypasses the first battery cell. The first BMS may include a first bi-directional communication interface in electrical communication with the first controller and the second BMS may include a second bi-directional communication interface in electrical communication with the second controller. The first and second bi-directional communication interfaces may be configured to communicate information between the first controller and the second controller. The first bi-directional communication interface may be configured to communicate the processed first battery cell measurement data to the second bi-directional communication interface. Likewise, the second bi-directional communication interface may be configured to communicate the processed second battery cell measurement data to the first bi-directional communication interface. The first battery cell measurement data may include first battery cell voltage data, first battery cell current data, first battery cell capacity data, and/or first battery cell temperature data. The first bi-directional communication interface may be configured to communicate that the control signal based on the processed first battery cell measurement data was produced to the second bi-directional communication interface. The first bi-directional communication interface may be configured to communicate information regarding the battery chemistry type or the cell capacity of the first battery cell to the second bi-directional communication interface. The control signals of the first and second controllers may also be based on the information communicated between the first controller and the second controller.

The first controller and the second controller may be configured to operate autonomously without user intervention to produce the control signals. The first controller may be configured to process the first battery cell measurement data by applying a machine learning algorithm. The machine learning algorithm may be configured to determine whether the first battery cell is experiencing a hazardous condition. The first battery cell may have a different battery chemistry type or a different cell capacity than the second battery cell. The first battery cell may be a lithium ion battery cell, while the second battery cell may be selected from the group consisting of a nickel-metal hydride battery cell, a lead-acid battery cell, and a sodium ion battery cell. The first battery cell may have a different cell capacity than the second battery cell.

The battery system may further include a third battery cell in the battery pack and a third BMS in communication with the third battery cell. The third BMS may include a third controller configured to receive measurement data for the third battery cell, to process the third battery cell measurement data, and to produce a control signal based on the processed third battery cell measurement data.

In another aspect, the present disclosure provides a battery system. The battery system may include a first battery management system (BMS) including first switching circuitry configured to control the connectivity of a first battery cell in a battery pack. The battery system may also include a second BMS including second switching circuitry configured to control the connectivity of a second battery cell in the battery pack.

The first switching circuitry may be further configured to connect, disconnect, bypass, and short the first battery cell. Likewise, the second switching circuitry may be further configured to connect, disconnect, bypass, and short the second battery cell. The first switching circuitry may includes a cell switch configured to control the electrical connection between the first battery cell and the battery pack, and a bypass switch configured to control the electrical connection on an electrical pathway of the battery pack bypassing the first battery cell. The first BMS may be configured to control the switching circuitry in order to actively balance the first battery cell. The first BMS may be configured to determine if the battery pack is not in use, and to disconnect the first battery cell if the battery pack is not in use. Similarly, the second BMS may be configured to determine if the battery pack is not in use, and to disconnect the second battery cell if the battery pack is not in use. The first BMS may be configured to determine if the first battery cell is experiencing a hazardous condition. The first BMS may be configured to control the first switching circuitry to disconnect the first battery cell if the first battery cell is experiencing a hazardous condition. The first BMS may be configured to control the first switching circuitry to bypass the first battery cell. The first BMS may be configured to communicate to the second BMS that the first battery cell is experiencing a hazardous condition.

In yet another aspect, the present disclosure provides a battery unit. The battery unit may include a battery cell and a housing enclosing the battery cell. The housing may be configured to provide electrical access between the battery cell and at least one battery cell not contained within the housing. The battery unit may also include a battery management system (BMS) coupled to the enclosure and in communication with the battery cell. The BMS may include a controller configured to receive measurement data for the battery cell, to process the battery cell measurement data, and to produce a control signal based on the processed battery cell measurement data.

The BMS may be contained within the housing. The housing may specifically not enclose an additional battery cell configured to be connected with the battery cell. The housing may include at least one electrical port configured to provide electrical access between the battery cell and at least one battery cell not contained within the housing. The distance separating the battery management system and the battery cell may be less than one half of the maximum width of the battery cell. The BMS may include a system memory configured to store measurement data of the first battery cell. The BMS may include a bi-directional communication interface configured to communicate information between the BMS and an additional BMS. The housing may be configured to provide electrical access between the bi-directional communication interface and the additional BMS. The housing may include at least one communication port configured to provide electrical access between the bi-directional communication interface and the additional BMS. The system memory may store information regarding the battery capacity, voltage, and battery chemistry of the battery cell, and the BMS may be configured to communicate this information to the additional BMS.

In another aspect, the present disclosure provides an energy storage system. The energy storage system may include a first energy storage cell and a first energy storage management system (ESMS) in communication with the first energy storage cell. The first ESMS may include a controller configured to receive measurement data for the first energy storage cell, to process the first energy storage cell measurement data, and to produce a control signal based on the processed first energy storage cell measurement data. The energy storage system may also include a second energy storage cell in communication with the first energy storage cell and a second ESMS in communication with the second energy storage cell. The second ESMS may include a controller configured to receive measurement data for the second energy storage cell, to process the second energy storage cell measurement data, and to produce a control signal based on the processed second energy storage cell measurement data. The first energy storage cell may be a capacitor, a supercapacitor, or a fuel cell. The second energy storage cell may be a battery cell. Alternatively, the second energy storage cell may be a capacitor, a supercapacitor, or a fuel cell.

In the descriptions above and in the claims, phrases such as “at least one of” or “one or more of” may occur followed by a conjunctive list of elements or features. The term “and/or” may also occur in a list of two or more elements or features. Unless otherwise implicitly or explicitly contradicted by the context in which it is used, such a phrase is intended to mean any of the listed elements or features individually or any of the recited elements or features in combination with any of the other recited elements or features. For example, the phrases “at least one of A and B;” “one or more of A and B;” and “A and/or B” are each intended to mean “A alone, B alone, or A and B together.” A similar interpretation is also intended for lists including three or more items. For example, the phrases “at least one of A, B, and C;” “one or more of A, B, and C;” and “A, B, and/or C” are each intended to mean “A alone, B alone, C alone, A and B together, A and C together, B and C together, or A and B and C together.” In addition, use of the term “based on,” above and in the claims is intended to mean, “based at least in part on,” such that an unrecited feature or element is also permissible.

The subject matter described herein can be embodied in systems, apparatus, methods, and/or articles depending on the desired configuration. The implementations set forth in the foregoing description do not represent all implementations consistent with the subject matter described herein. Instead, they are merely some examples consistent with aspects related to the described subject matter. Although a few variations have been described in detail above, other modifications or additions are possible. In particular, further features and/or variations can be provided in addition to those set forth herein. For example, the implementations described above can be directed to various combinations and subcombinations of the disclosed features and/or combinations and subcombinations of several further features disclosed above. Other implementations may be within the scope of the following claims.

What is claimed is:

1. A battery system comprising:
a first battery cell in a battery pack;
a first battery management system (BMS) in communication with the first battery cell, the first BMS including:
a first controller configured to receive measurement data for the first battery cell, to process the first battery cell measurement data, and to produce a control signal based on the processed measurement data from the first battery cell;
a second battery cell in the battery pack; and
a second BMS in communication with the second battery cell, the second BMS including:
a second controller configured to receive measurement data for the second battery cell, to process the second battery cell measurement data, and to produce a control signal based on the processed measurement data from the second battery cell.

2. The system of claim 1, wherein the first controller is configured to determine the state of charge and state of health of the first battery cell when processing the first battery cell measurement data; and
wherein the second controller is configured to determine the state of charge and state of health of the second battery cell when processing the second battery cell measurement data.

3. The system of claim 1, wherein the first BMS further includes switching circuitry configured to disconnect the first battery cell from the battery pack, wherein the switching circuitry is configured to receive the control signal based on the first battery cell measurement data and to disconnect the first battery cell from the battery pack for safety or performance.

4. The system of claim 1, wherein the first controller is configured to process the first battery cell measurement data to determine if the first battery cell is experiencing a hazardous condition and to produce the control signal only if the first battery cell is experiencing a hazardous condition.

5. The system of claim 1, wherein the first controller includes a first system memory configured to store the first battery cell measurement data, the processed measurement data from the first battery cell, or the control signal provided by the first controller; and
wherein the second controller includes a second system memory configured to store the second battery cell measurement data, the processed measurement data from the second battery cell, or the control signal provided by the second controller.

6. The system of claim 1, wherein the first BMS includes a first bi-directional communication interface in electrical communication with the first controller and the second BMS includes a second bi-directional communication interface in electrical communication with the second controller, and wherein the first and second bi-directional communication interfaces are configured to communicate information between the first controller and the second controller.

7. The system of claim 6, wherein the control signals of the first and second controllers are also based on the information communicated between the first controller and the second controller.

8. The system of claim 7, wherein the first BMS further includes a first temperature sensor configured to measure the temperature of the first battery cell, and the first battery cell measurement data includes temperature data; and
wherein the second controller is configured to produce the control signal based on both the processed measurement data from the second battery cell and the temperature data measured by the temperature sensor of the first BMS.

9. The system of claim 1, wherein the first battery cell has a different battery chemistry type or a different cell capacity than the second battery cell.

10. The system of claim 1, wherein the first controller and the second controller are configured to operate autonomously without user intervention to produce the control signals.

11. A battery system comprising:
a first battery management system (BMS) including first switching circuitry configured to control the connectivity of a first battery cell in a battery pack;
a second BMS including second switching circuitry configured to control the connectivity of a second battery cell in the battery pack.

12. The battery system of claim 11, wherein the first switching circuitry is further configured to connect, disconnect, bypass, and short the first battery cell, and
wherein the second switching circuitry is further configured to connect, disconnect, bypass, and short the second battery cell.

13. The battery system of claim 11, wherein the first switching circuitry includes:
a cell switch configured to control the electrical connection between the first battery cell and the battery pack; and
a bypass switch configured to control the electrical connection on an electrical pathway of the battery pack bypassing the first battery cell.

14. The battery system of claim 11, wherein the first BMS is configured to determine if the battery pack is not in use, and to disconnect the first battery cell if the battery pack is not in use; and
wherein the second BMS is configured to determine if the battery pack is not in use, and to disconnect the second battery cell if the battery pack is not in use.

15. The battery system of claim 11, wherein the first BMS is configured to determine if the first battery cell is experiencing a hazardous condition, and
wherein the first BMS is configured to control the first switching circuitry to disconnect or bypass the first battery cell if the first battery cell is experiencing a hazardous condition.

16. A battery unit comprising:
a battery cell;
a housing enclosing the battery cell, wherein the housing is configured to provide electrical access between the battery cell and at least one battery cell not contained within the housing;
a battery management system (BMS) coupled to the enclosure and in communication with the battery cell, the first BMS including:
a controller configured to receive measurement data for the battery cell, to process the battery cell measurement data, and to produce a control signal based on the processed measurement data from the battery cell.

17. The battery unit of claim 16, wherein the BMS is contained within the housing.

18. The battery unit of claim 17, wherein the housing does not enclose an additional battery cell configured to be connected with the battery cell.

19. The battery unit of claim 16, wherein the housing includes at least one electrical port configured to provide electrical access between the battery cell and at least one battery cell not contained within the housing.

20. The battery unit of claim 16, wherein the BMS includes a bi-directional communication interface configured to communicate information between the BMS and an additional BMS, and
wherein the housing includes at least one communication port configured to provide electrical access between the bi-directional communication interface and the additional BMS.
